(19) United States
(12) Patent Application Publication
(10) Pub. No.: US 2013/0087200 A1
(43) Pub. Date: Apr. 11, 2013

(54) ENHANCED THIN FILM SOLAR CELL PERFORMANCE USING TEXTURED REAR REFLECTORS

(71) Applicants: Jiangeng Xue, Gainesville, FL (US); Jason David Myers, Gainesville, FL (US); Weiran Cao, Gainesville, FL (US)

(72) Inventors: Jiangeng Xue, Gainesville, FL (US); Jason David Myers, Gainesville, FL (US); Weiran Cao, Gainesville, FL (US)

(73) Assignee: UNIVERSITY OF FLORIDA RESEARCH FOUNDATION, INC., GAINESVILLE, FL (US)

(21) Appl. No.: 13/704,660

(22) PCT Filed: Jun. 17, 2011
(86) PCT No.: PCT/US11/40880

§ 371 Date: Dec. 17, 2012

Related U.S. Application Data
(60) Provisional application No. 61/355,891, filed on Jun. 17, 2010.
(60) Provisional application No. 61/356,267, filed on Jun. 18, 2010.

(51) Int. Cl. H01L 31/0232; H01L 31/18

(52) U.S. Cl. CPC H01L 31/02327; H01L 31/18; B82Y 99/00
USPC 136/259; 438/69; 977/948

(57) ABSTRACT

Back reflector arrays are applied to the surface distal to the incident light receiving surface of a thin film solar cell to increase its efficiency by altering the reflected light path and thereby increasing the path length of light through the active layer of the solar cell. The back reflector is an array of features of micrometer proportions. The feature may be concave or convex features such as hemispheres, hemi-ellipsoids, partial-spheres, partial-ellipsoids, or combinations thereof The feature may be pyramidal. A method of forming the back reflector array is by forming an array of features from a photocurable resin, subsequent curing the resin and metalizing the cured resin to render the surface reflective. The photocurable resin can be applied by inkjet printing or rolling or stamping with a mold.

### CROSS-REFERENCE TO RELATED APPLICATIONS

The present application claims the benefit of U.S. Provisional Application Ser. No. 61/356,267, filed Jun. 18, 2010, and U.S. Provisional Application Ser. No. 61/355,891, filed Jun. 17, 2010, the disclosures of which are incorporated by reference herein in their entireties, including any figures, tables, or drawings.

The subject invention was made with partial government support under the National Science Foundation, Grant No. ECCS-0644690, and U.S. Department of Energy Solar Energy Technologies Program, Grant No. DE-FG36-08G018020. The government has certain rights to this invention.

### BACKGROUND OF INVENTION

The pursuit of energy sources that do not require the use of a carbon based fuel, particularly a hydrocarbon, is vigorously pursued. Solar cells are an important technology towards such ends. Solar energy is abundant, as the earth receives the equivalent energy from the sun in about an hour as is generated by man in a year. The cost to implementing solar energy involves many factors, but a predominate factor is the efficiency of a solar cell to convert as much of the solar energy reaching the surface of the solar cell to electrical energy as possible. Although many types of solar cells exist, generally differentiated by the nature of the photoactive material used to generate free electrical charge carriers in the cell, the performance of a solar cell of any given photoactive material can vary by a significant amount depending on various designed factors.

Although increasing the device thickness can dramatically increase the amount of light absorbed, the amount converted to electricity can be low because light-generated charge carriers may recombine before they move through a thick film via diffusion or drift processes and are collected at the electrodes. Hence, because of charge recombinant loss, thinner solar cells can have higher internal quantum efficiencies and optimized solar cells often have an optical path length that is several times the actual active layer thickness. The optical path length of a device is the distance that an unabsorbed photon travels within the device before escaping the device.

One way to increase the optical path length is to use a reflector on the distal surface of the cell with respect to the light source. A commonly used reflector is a Lambertian back reflector where the light reflected from the reflectors surface is isotropic. The use of the randomizing reflector reduces absorption in the rear cell contacts and prohibits transmission through the distal surface. By randomizing the light path, much reflected light is totally internally reflected at the exposed surface when the angle between the exposed surface and the light path is greater than the critical angle for total internal reflection. The Lambertian back reflector can be formed by covering the distal surface of the solar cell with a paint or paste, for example an Al or Ag paste, that can be sprayed or screen printed on the surface.

Another common reflector is a V-groove reflector. Generally the V-groove is etched at the face of a 1-0-0 surface crystal orientation to form a silicon active region with one face of the V-grooves is n doped and the other p doped and subsequently metalized to form the cell. Such direct etching processes are viable for crystalline solar cells.

The formation of a back reflector on a thin film solar cell, particularly for amorphous silicon solar cells has been focused on mechanical texturing using abrasive particles, lithographic patterning, plasma etching, chemical etching, laser enhanced chemical etching, deposition for the growth of large crystallites, and anisotropic chemical etching. Surface recombination of charge carriers is a potential issue for thin-film solar cells with surface textures. With a thickness of a few microns or less, the texture feature's size needs to be at a subwavelength level, which leads to significantly increases surface areas. The inevitable presence of electrically active centers or defects at the surface tends to increase surface-recombination losses and reduce the performance of such solar cells. Simple low-cost methods to form back reflectors on thin-film solar cells, including organic or hybrid organic-inorganic materials based solar cells, without increasing surface recombination, are desired. Furthermore, it is advantageous if the back reflectors can be incorporated into the solar cell without modification of other existing device fabrication processes.

### BRIEF SUMMARY

Embodiments of the invention are directed to thin film solar cells having a back reflector on the surface of the cell oriented distal to the light source. In some embodiments of the invention, the hack reflector has an array of concave or convex reflective features of 1 to 1,000 μm in cross-section formed on an essentially flat surface. The back features can be hemispheres, hemi-ellipsoids, partial-spheres, partial-ellipsoids or any combination thereof where the features can have identical cross-sections or a plurality of different cross-sections. The array of features can formed as part of a transparent substrate or formed on a photo-cured transparent resin, such as an optical adhesive, deposited on a transparent substrate or a transparent electrode with a reflective metal deposited on the features. The metal can be, for example, aluminum, silver, gold, iron, or copper.

In other embodiments of the invention, the back reflector is an array of pyramidal features of 1 to 1,000 μm in cross-section on an essentially flat surface. The pyramids can have triangular, square or hexagonal bases and can be a combination of pyramids of different shapes and sizes. The back reflector has a reflective metal deposited on surface having the pyramidal features which can be a photo-cured transparent resin such as an optical adhesive. Possible metals include aluminum, silver, gold, iron, or copper.

The thin solar cell can be of any type according to embodiments of the invention. In one embodiment of the invention, the active layer comprises an inorganic semiconducting thin film, such as an amorphous, nanocrystalline, microcrystalline, or polycrystalline silicon, silicon germanium, CdTe, CdS, GaAs, Cu₂S, CuInS₂, CuZnSn(S,Se), or Cu(InₓGa₁₋ₓ)Se₂. In another embodiment of the invention, the active layer comprises an organic semiconducting thin film, which can be a small molecular weight organic compound or a conjugated polymer based film. In another embodiment of the invention, the active layer comprises a hybrid organic-inorganic semiconducting thin film comprising inorganic nanoparticles combined with a conjugated polymer or small molecular weight organic compound.

In some embodiments of the invention, the solar cell can include a top transparent textured surface layer on the surface proximal to the incident light, where the texture surface comprises an array of top features of 1 to 1,000 μm in cross-section deposited on an essentially flat surface, wherein at least 60% of the flat surface is occupied by the features. The top features can be hemispheres, hemi-ellipsoids, partial-spheres, partial-ellipsoids, cones, pyramids prisms, half cylinders or any combination thereof having equivalent or a plurality of different cross-sections. The top surface layer can be a photo-cured or thermal-cured resin, for example an optical adhesive.

Embodiments of the invention are directed to a method of forming a back reflector that comprises an array of features on a surface of a thin film solar cell. When the features are concave or convex reflective features, an array of features is formed on a surface of a photocurable or thermally curable transparent resin and the transparent resin is cured by exposure to electromagnetic radiation or heat, which fixes the array of features and adheres the array to the surface of a transparent substrate or a transparent electrode. In another embodiment of the invention, transparent inorganic nanoparticles, such as TiO₂, ZrO₂, CeO₂, or lead zirconate tinate (PZT) nanoparticles, may be incorporated in the photocurable transparent resin to increase the index of refraction of such resin. A reflective metal is deposited on the cured array of features. In one embodiment of the invention, the transparent resin with concave features can be formed by inkjet printing the transparent resin onto the surface of the transparent substrate or transparent electrode in the shape of the features. In another embodiment of the invention, the array of concave or convex features is formed by depositing a layer of the transparent resin on the surface and subsequently contacting the layer with a mold having a template of the concave or convex reflective features. Contacting can be carried out in a roll to roll process.

Other embodiments of the invention are directed to methods of forming a back reflector comprising an array of pyramidal features on a flat surface of a thin film solar cell. An array of features can be formed in a photocurable or thermally curable transparent resin on a surface of a transparent substrate or a transparent electrode, the transparent resin can be cured by irradiation with electromagnetic radiation or heat to fixed the features and adhere them to the surface, and a metal can be deposited on the cured array of features. In one embodiment of the invention, a layer of a photocurable transparent resin is deposited on the surface of the transparent substrate or electrode, which is contacted by a mold having a template of the features to form the array of pyramidal features upon irradiation while the mold is present or after its removal. The mold can be contacted by a roll to roll imprinting process or a stamping process.

In embodiments of the invention, a method of forming a solar cell having a back reflector comprising an array of pyramidal features involves molding an array of features on a face of a transparent substrate, depositing a metal on the array of features, and depositing a transparent electrode on a second face of the transparent substrate that is opposite the array of pyramidal features. In one embodiment of the invention, the substrate is a theinioplastic sheet to which a mold is contacted. The mold and/or the thermoplastic sheet can be heated. In another embodiment of the invention, a mold can be filled with a thermosetting resin and subsequently cured thermally or photochemically to form the transparent substrate with the array of pyramidal features. In another embodiment of the invention, a mold, having a template of the array of pyramidal features, is filled with a thermosetting resin that is subsequently cured thermally or photochemically to form the transparent substrate having the templated array of pyramidal features on one surface. In another embodiment of the invention a mold having a template of the array of pyramidal features is filled with molten glass to yield a transparent glass substrate with an array of pyramidal features on one surface after solidification of the glass.

### BRIEF DESCRIPTION OF DRAWINGS

FIG. 1 shows schematics for thin-film solar cells having concave (right) and convex (left) back reflectors in accordance with embodiments of the subject invention.

FIG. 2 shows solar cells having a pyramidal reflector array according to embodiments of the invention.

FIG. 3 shows a schematic of a prior art solar cell having a flat reflective metallic electrode on the side of the solar cell that is distal to the light source.

FIG. 4 shows a schematic of a convex rear reflector where an incident light beam is projected at an angle from the curved reflector surface according to an embodiment of the invention.

FIG. 5 shows: a) the top-view of an exemplary pyramidal reflector array according to an embodiment of the invention, where b) the cross-section geometry of the square pyramids include a base of 20 μm, a height of 5.77 μm, and a pitch of 30°.

FIG. 6 shows a truncated solar cell having a pyramidal reflector array with the geometric considerations to determine the minimal pitch angle of a pyramid for the pyramidal reflector array according to embodiments of the invention.

FIG. 7 shows a truncated solar cell having a pyramidal reflector array with the geometric considerations to determine the maximal pitch angle of a pyramid for the pyramidal reflector array according to embodiments of the invention.

FIG. 8 shows a solar cell having deposited hemispherical microlenses to refract incident light and to redirect reflected light into the active layer of the solar cell at an angle so as to increase the light path through the active layer in accordance with an embodiment of the invention.

FIG. 9 shows a scheme for forming a substrate having an array of pyramidal features by contacting a mold with a thermoplastic sheet to form a transparent substrate having a surface with a pyramidal array that can be rendered reflective and an opposing flat surface for deposition of an active layer of a solar cell according to an embodiment of the invention.

FIG. 10 shows (a) a schematic illustration of an organic solar cell (OSC), constructed as indicated in (b) with a pyramidal rear reflector external to a glass substrate according to an embodiment of the invention, where (c) the formation of the pyramidal rear reflector on the glass substrate of the OSC is indicated from formation of a mold for the reflector, its attachment to the glass substrate of the OSC through the metallization of the molded pyramid.

FIG. 11 shows (a) a current density-voltage (J-V) plot for small area P3HT:PCBM OSCs under 1 sun simulated AM 1.5G solar illumination for devices with planar or pyramidal reflectors where (b) shows the light intensity for light from the single reflector over the area of the reflector where the solid square represents a small area OSC concentric with the pyramid and the dashed square represents a small area OSC near an edge of the pyramid.

FIG. 12 shows plots of the shirt-circuit current density, f, for small area OSCs as a function of the active layer thickness tₐ for small area devices (2×2 mm²) aligned at the center or edge of the pyramid, experimental data are lower than calculated lines where inserts show the light paths for OSCs with planar or pyramidal rear reflector.

FIG. 13 shows plots of (a) calculated the short-circuit current density, f, as a function of the active layer thickness tₐ for large area devices (1×1 cm₂) (Calc. 1) where experimental agrees well where differences primarily occur because of the glass thickness and absorption and scattering losses for the TP and electrodes where (b) is a plot of the optical transmittance, T, as a function of wavelength, λ, for the ITO electrode, OMO trilayer electrode and the TP.

### DETAILED DISCLOSURE

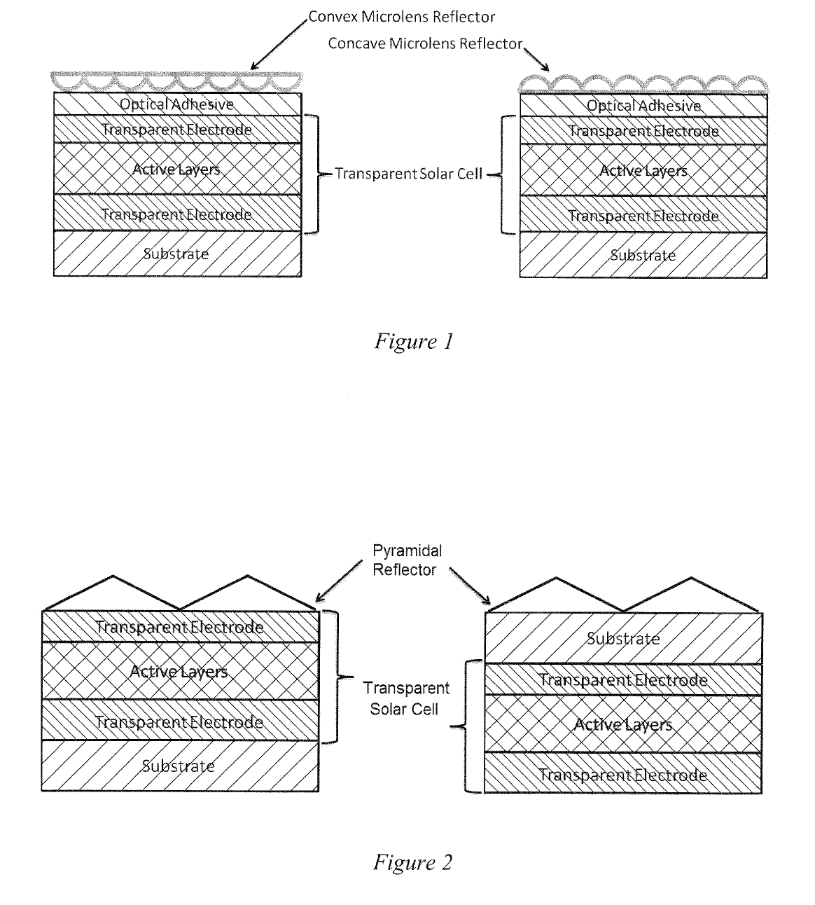

Embodiments of the invention are directed to back reflectors, thin-film solar cells comprising these reflectors, and a method of forming the reflector on a thin film solar cell. Reflectors according to an embodiment of the invention are an array of concave or convex features with micrometer dimensions including hemispherical, as shown in FIG. 1, other hemi-ellipsoidal, or partial ellipsoidal shapes that will alter the path of reflected light relative to that of a flat reflector, where the features fill a significant portion, 60% or more, of the surface. The array of concave or convex features can be periodic, quasiperiodic, or random. Reflectors, according to another embodiment of the invention, comprise a continuous periodic array of pyramidal features with micrometer dimensions, as shown in FIG. 2. The pyramidal reflectors alter the path of reflected light relative to that of a flat reflector where the features fill nearly the entire distal surface.

The surface of the features, as well as any exposed surface between the features, is coated with a reflective material, for example a metal such as aluminum, silver or copper. The features can be non-overlapping or overlapping. Increases in short-circuit current and power conversion efficiency of 10%, 25%, or more can be achieved relative to solar cells having planar reflectors. In other embodiments of the invention, a top textured surface layer is situated on the light proximal surface of the solar cell opposite the back reflector to further enhance the efficiency of the solar cell.

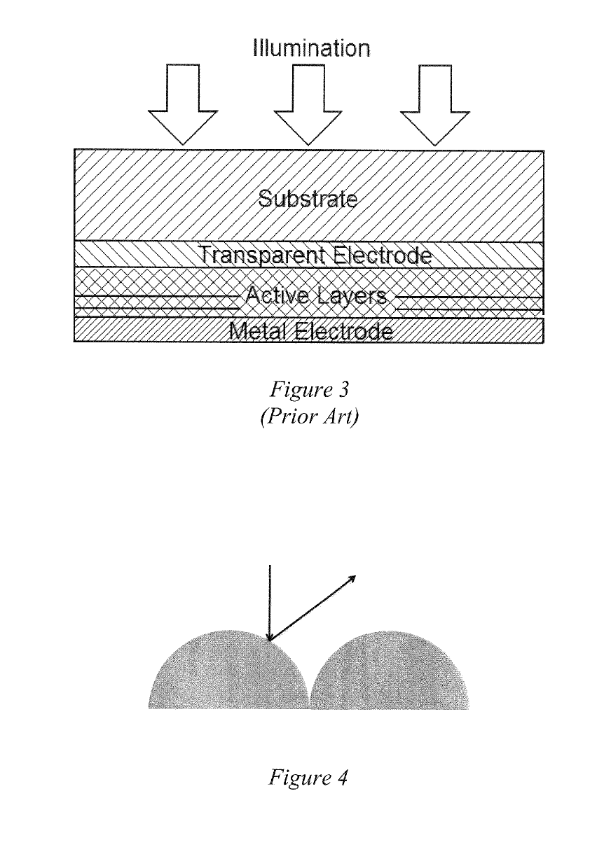

Typical bulk heterojunction organic solar cells, as shown in FIG. 3, are intrinsically limited in the thickness of the active layer because photo-generated charge carriers have a mean collection length on the order of less than 100 nm prior to recombination, requiring that the active layer thickness be of about the mean collection length to optimize current per volume of active material.

Materials that can be used in organic thin film solar cells, according to embodiments of the invention, can be of various designs, such as bulk or planar heterojunction solar cells that employ electron donors such as: phthalocyanines of Copper, Zinc, Nickel, Iron, Lead, Tin, or other metals; pentacene; thiophenes, such as sexithiophene, oligothiophene, and poly(3-hexylthiophene); rubrene; 4,4-bis[N-(1-naphthyl)-N-phenyl-amino]biphenyl (NPD); poly[2,6-(4,4-bis-(2-ethylhexyl)-4H-cyclopenta[2,1-b;3,4-b′]dithiophene)-alt-4,7-(2,1,3-benzothiadiazole)] (PCPDTBT); poly(vinylpyridines), such as poly(1-methoxy-4-(2-ethylhexyloxy)-p-phenylenevinylene) (MEH-PPV) and poly[2-methoxy-5-(3′,7′-dimethyloctyloxy)-1,4-phenylenevinylene (MDMO-PPV); and inorganic nanoparticles such as CdS, CdSe, and PbSe; and employ electron acceptors such as: fullerenes such as C₆₀ and C₇₀; functionalized fullerenes such as phenyl-C61-butyric acid methyl ester (PC₆₁BM) and phenyl-C71-butyric acid methyl ester (PC₇₁BM); graphene; carbon nanotubes; perylene derivatives such as 3,4,9,10-perylenetetracarboxylic-bis-benzimidazole (PTCBI), perylene-3,4,9,10-tetracarboxylic-3,4,9,10-dianhydride (PTCDA), and perylene-3,4,9,10-tetracarboxylic-3,4,9,10-diimide (PTCDI); poly((9,9-dioctylfluorene)-2,7-diyl-alt-[4,7-bis(3-hexylthien-5-yl)-2,1,3-benzothiadiazole]-2,2-diyl) (F8TBT); and inorganic nanoparticles such as CdS, CdSe, PbSe, and ZnO. Exciton blocking layers such as: bathocuproine (BCP); ZnO; Bathophenanthroline (BPhen); and ruthenium(III) acetylacetonate (Ru(acac)₃) can be included with the active layer. Inorganic thin film solar cells, according to embodiments of the invention, can be constructed with: copper indium gallium diselenide (CIGS); copper zinc tin sulfides or selenides (CZT(S,Se)); II-VI or III-V compound semiconductors, such as CdTe CdS, and GaAs; and thin-film silicon, either amorphous, nanocrystalline, or black. Dye-sensitized solar cells are another form of thin-film solar cells that can be employed in an embodiment of the invention. This list of solar cell materials is not exhaustive and other thin-film solar cell materials can be employed with the reflector arrays disclosed herein to form improved solar cells.

In one embodiment of the invention, the array comprises reflective hemispheres of, for example, 100 μm in diameter. Other reflector diameters can be used, for example 1 to 1,000 μm. A dramatic increase of the light path length within the active layer of an organic solar cell results in a significant increase of light absorption and solar cell performance relative to that of a flat surface. As the reflector surface is curved, a large proportion of the light is reflected at a sufficient angle such that the reflected light makes a subsequent pass through the active layer and is directed toward the top surface at an angle that is greater than the critical angle for total internal reflection at the top surface, which further increase the light path length and the amount of light ultimately absorbed by the active layer of the solar cell.

The array of concave or convex reflectors can be of a single size, a continuous distribution of sizes, or comprised of a plurality of discrete sizes. For example, in one embodiment, non-overlapping reflectors are of nearly identical size and situated in a closed packed array on a plane. In this manner up to about 91% of the reflector surface is not normal to the incoming light. In another embodiment the non-overlapping reflectors can be of two sizes, where the voids of a closed packed orientation of the large reflectors on the plane of the substrate are occupied by smaller reflectors, which increase the proportion of the surface occupied by reflectors in excess of 91%. In like manner, even smaller reflectors can be constructed in the void area that result for the close packed distribution of two non-overlapping reflectors to further increase the lens occupied surface. By having a surface of overlapping spheres, the proportion of reflector covered surface can be nearly 100%. In embodiments of the invention concave or convex reflectors cover about 60% or more of the surface.

For virtually all active materials, the optical path required to absorb all incident light is significantly larger than the desired thickness to minimize recombination, for example, greater than 100 nm for organic-based thin films or greater than 1 μm for inorganic semiconductor thin films. The convex, as shown in FIG. 4, or concave reflectors modify the reflected light path, such that any light ray striking the reflector is directed from the reflector at an angle determined by the normal vector to the surface that the light ray impacts, which is a surface that has a low probability of being effectively flat along the curve of the reflector. Therefore, the reflected light is transmitted through the overlaying active layer with a longer light path than that from a typical flat reflector surface and a large proportion of the reflected light can strike the opposing air surface at an angle where total reflectance occurs. As the light path length through the active layer increases, the absorption probability of that light within the active layer increases according to equation 1:

A~1−e^{-ad} (Equation 1),

where a is the effective absorption coefficient of the active layer material and d is the path length.

Solar cells, according to embodiments of the invention, which contain arrays of concave or convex rear reflectors, are shown in FIG. 1, where the light path reflectance by an array of convex reflectors is shown in FIG. 4. The solar cells employ two transparent electrodes. Transparent electrodes can be, for example: indium-doped tin oxide (ITO); fluorine-doped tin oxide (FTO); aluminum-doped zinc oxide (AZO); gallium doped zinc oxide (GZO); graphene; carbon nanotubes; conductive polymers, such as polyethylenedioxythiophene: polystyrenesulfonate (PEDOT:PSS); metal oxide/metal/metal oxide multi-layers, such as MoOx/Au/MoOx; thin metallic layers, for example Au, Ag, or Al, metal gratings; and metallic nanowire networks. The array of reflectors is adhered by a resin that is of a desired refractive index to one of the transparent electrodes or to a substrate, such as glass or plastic, supporting the electrode. A desired refractive index is one such that the reflected light is primarily directed into the active layer of the solar cell rather than being reflected off the transparent electrode or its supporting substrate to the reflector.

In another embodiment of the invention, the array comprises reflective pyramids of, for example, 20 μm in cross section. Other pyramid cross sections can be used, for example 1 to 1,000 μm. In terms of performance enhancement for the solar cell, the size of these pyramids should not have any significant influence, as long as the pitch angle remains the same. Therefore pyramid cross sections up to a few cm could be used. However, the pyramid layer needs to be thin; hence, the pyramids are small to avoid the significant change in the form factor of the thin-film solar cell. Advantageously, the amount of material needed to fabricate the pyramid array over a fixed area decreases with the cross section of the pyramids for any given pitch angle. Therefore 1,000 μm, or 1 mm, is a practical upper limit for the size of the pyramids, although, in principle, any larger size should provide similar level of efficiency enhancement. The reflectors increase the light path length within the active layer of an organic solar cell, resulting in a significant increase of light absorption and solar cell performance relative to that of a flat reflector. Additionally, the pitch of the reflective faces from the base to the peak of the pyramidal features is at an angle relative to the smooth top surface of the solar cell proximal to the light source, which directs the incident light reflected to the light source proximal surface such that total internal reflection occurs at that top surface.

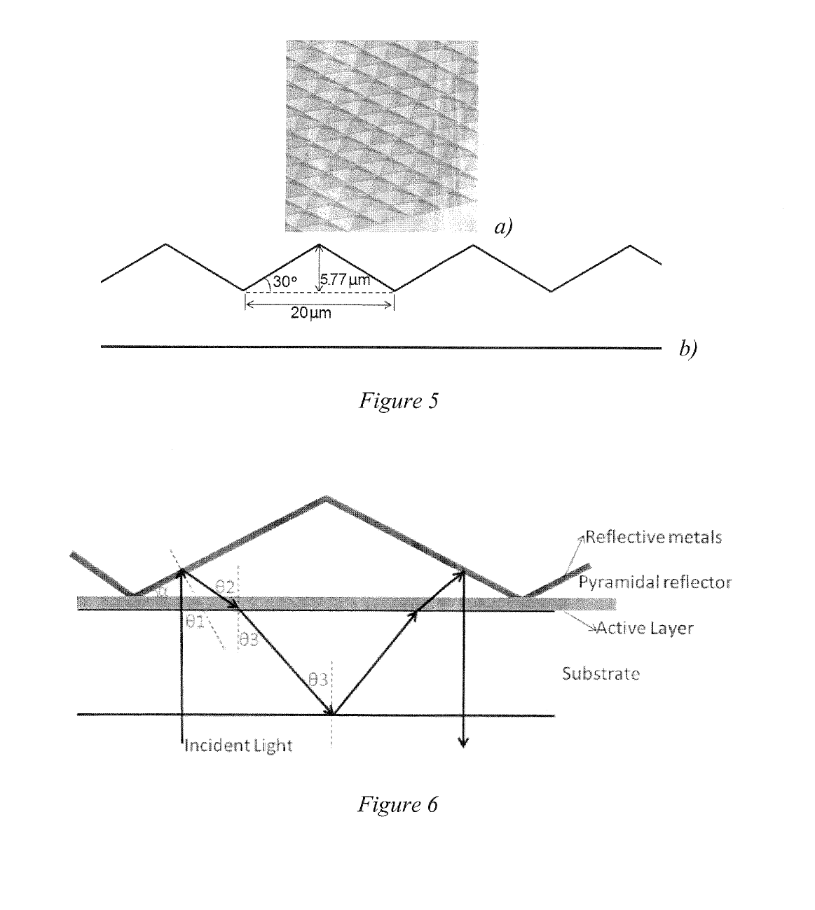

The array of pyramidal reflectors can be of a single size and shape, or can he comprised of a plurality of discrete sizes and shapes, such that the entire light distal surface of any sized solar cell is covered with pyramidal reflectors. The pyramids can be triangular, square, hexagonal, or any other shape. For example, in one embodiment of the invention, illustrated in FIG. 5, square pyramidal reflectors are of nearly identical size with a 20 to 200 μm base and a 30° angled face relative to the plane of the surface upon which it rests and the plane of the opposing top surface. In another embodiment of the invention, for example, an equal number of larger octagonal pyramids and smaller square pyramids can be periodically positioned to cover the entire surface. All pyramids are constructed with a pitch of the reflective faces that assures total internal reflection at the top surface. In this manner the light entering the solar cell must make at least four passes through the active layer and at least two passes through the active layer with a path length greater than that of the active layer's thickness.

As illustrated in FIG. 6 for a pyramidal reflector disposed on a solar cell, the reflected light is transmitted through the active layer with a longer light path than the thickness of the active layer, where the reflected light striking the light source proximal face at an air surface is totally reflected back into the solar cell. As the light path length through the active layer increases, the absorption probability of that light within the active layer increases according to equation 1, above.

As shown in the FIG. 6, the incident light beam is perpendicular to the active layer and the angle θ₁ is equal to the pitch angle of the pyramidal reflector, a, (θ₁=a). The incident light is then totally reflected by the reflective metals, at an angle θ₂, where θ₂=2θ₁=2a. Refraction occurs at the interface of the material that comprises the pyramidal feature and the substrate according to the Snell's law relationship, equation 2:

nₚ·sin θ₂=nₛ·sin θ₃ (Equation 2),

where nₛ and nₚ are the refractive indexes of the substrate and pyramidal material, respectively. In this treatment, the solar cell's transparent electrodes and active layer are neglected, as their thinness causes minimal distortion of the light path. The light beam is totally internal reflected at the substrate and air interface when the incident angle, θ₃, is larger than the critical angle, θ₃=θ_{c}, where sin θ_{c}=n₀/ns and n₀ is the refractive index of air. Total internal reflection requires that the angle of the pyramids is given by equation 3:

sin 2a=n₀/nₚ (Equation 3),

where the angle of the reflector face is independent of the substrate material and can be applied to any transparent substrate. For example, if the refractive index of the materials used for form the pyramidal reflector and the glass substrate is 1.5, the angle of the pyramid, a, should be larger than 20.9°.

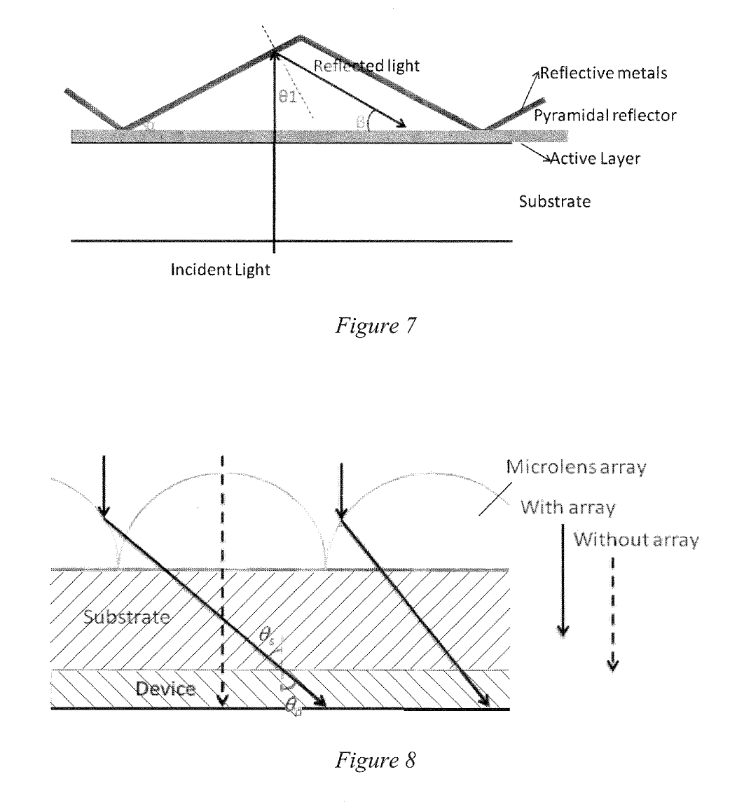

Another requirement for the light trapping system is to avoid reflected light hitting the side walls of the pyramidal reflectors. As shown in FIG. 7, to achieve this condition, the angle between the reflected light and the active layer β should be larger than the pyramids angle a. Therefore β is determined by the pyramids angel by equation 4:

β=90°−2a (Equation 4),

and the pyramids angle a should be smaller than 30°. Over all, the angle of the pyramidal reflectors is confined to a range depending on the refractive index of the material used for the pyramids, for example 20.9°=α=30° to achieve the light trapping in the thin film solar cell devices, where nₚ is 1.5. In this manner, the geometry of the array of pyramids can be determined by the known optical properties of substrate and pyramidal reflector materials.

Solar cells that contain arrays of pyramidal rear reflectors, as shown in FIG. 2, employ two transparent electrodes. The array of reflectors is adhered to one of the transparent electrodes or to a substrate supporting an electrode by a resin that is of a desired refractive index. A desired refractive index is one where the light reflected from the reflective face of the pyramid is primarily directed into the active layer of the solar cell rather than being reflected off the transparent electrode or its supporting substrate to the reflector. Transparent electrodes include, but are not restricted to: indium-doped tin oxide (ITO); fluorine-doped tin oxide (FTO); aluminum-doped zinc oxide (AZO); gallium doped zinc oxide (GZO); graphene; carbon nanotubes; conductive polymers such as polyethylenedioxythiophene:polystyrenesulfonate (PEDOT:PSS); metal oxide/metal/metal oxide multi-layers such as MoOx/Au/MoOx; thin metallic layers for example Au, Ag, or Al, metal gratings; and metallic nanowire networks.

In other embodiments of the invention, in addition to the reflector array deposited on one side of the solar cell, a textured surface can be formed on the light exposed surface, often referred to as a top or front surface, of a thin-film solar cell such that the light absorption is enhanced and incident light reflection is discouraged. This top texture surface can be generated and applied economically to a large surface area device. The top textured surface can be formed using a low cost material with a low cost scalable method on large area organic solar cells. The top textured surface can be an array, of features with micrometer dimensions including lenses (for example hemispherical, other hemi-ellipsoidal or partial ellipsoidal), cones, pyramids (for example triangular, square, or hexagonal), prisms, half cylinders, or any other shape or combination of shapes that will alter the path of incoming light relative to that of a flat surface, and where the features fill a significant portion, 60% or more, of the surface. The top features can be non-overlapping or overlapping. The top array can be a periodic, quasiperiodic, or random. Increases in short-circuit current and power conversion efficiency of 20-30% or more can be achieved relative to solar cells having unmodified planar exposed surfaces.

A top array of features can be, for example, hemispherical microlenses of, for example, 100 μm in diameter. Other lens diameters can be used, for example, 1 to 1,000 μm, where typically the diameter of the lens does not exceed the thickness of the substrate upon which it is deposited. A dramatic decrease of surface reflectance, and increase of the light path length within the active layer of an organic solar cell, results in a significant increase of light absorption and solar cell performance relative to that of a flat surface. For example, where a flat surface of a photovoltaic device has been directed towards the sun in an orientation where the surface is normal to incident sunlight, light is reflected directly back along its previous path (approximately 4% for common glass substrates) or transmitted through the surface with no change in direction. This ray proceeds through the active layer of the device with a path length equal to the thickness of the active layer. When the lens array is applied, the light ray changes direction when entering the active area of the device, as shown as solid lines in FIG. 8, leading to an increased light path length to enhance light absorption.

The top array of microlenses can be of a single size, a continuous distribution of sizes, or comprised of a plurality of discrete sizes. For example, in one embodiment, non-overlapping hemispherical lenses are of nearly identical size and closed packed on a plane. In this manner, up to about 91% of the surface is not normal to the incoming light. In another embodiment of the invention, the non-overlapping lenses can be of two sizes, where the voids of a closed packed orientation of the large lenses on the plane of the substrate are occupied by smaller lens, which increase the proportion of the surface occupied by lenses in excess of 91%. In like manner, smaller lenses can be constructed in the voids that result for the close packed distribution of two non-overlapping lenses to further increase the lens occupied surface. By having a surface of overlapping spheres, the proportion of lens covered surface can be close to 100%. In embodiments of the invention microlenses cover about 60% or more of the surface.

In other embodiments of the invention the shape of the top features can be cones or pyramids where the angle of the features surface to the substrates surface can be predetermined to optimize impingement of light reflected from one feature on another feature to minimize the loss of light by reflectance. Whereas like sized pyramids can be in a regular array that minimizes surfaces normal to the incoming light, cones can be overlapping or of multiple dimensions to have features covering nearly the entire surface.

For virtually all thin-film materials, the minimum optical path that absorbs all incident light is much greater than the film thickness, for example, greater than 100 nm for organic-based thin films, or greater than 1 μm for inorganic semiconductor thin films. A top array comprising microlenses, according to an embodiment of the invention, is not used to focus the light to a particular spot or area in the solar cell, rather the lenses modify the light path such that any ray striking the lenses undergoes refraction at an angle determined by the normal vector of the surface that it impacts, which has a low probability of being effectively flat along the curve of the lens. Therefore, the refracted light transmitted through the textured surface has a longer path through the underlying active layer than it otherwise would have at a normal flat surface because of the angle of refraction. Additionally, unlike a planar surface where all light reflected at the proximal surface is lost to the device; a light ray reflected from the textured top surface is not necessarily lost, depending on the angle of reflection and shape of the surface. Refracting the light through the device at an angle by the top surface texturing results in a greater path length through the active layer, and increases the absorption probability of that light within the active layers according to equation 1, above, that described this effect imparted by the array of reflectors.

The surface area of the top textured surface can be greater than the surface area of the photoactive layer of the device and can direct additional light into the active layer at an angle that imparts a greater path length. Surface texturing results in a more effective device as the surface area of the device increases. The percentage of light lost is proportional to the perimeter of the photovoltaic device. As the device size increases, the percentage of light lost becomes smaller as the device area increases faster than the perimeter length. The increase of efficiency with surface area occurs even where the area of the top textured surface is equal to the area of the active layer. The device improvement by inclusion of the top textured surface is greatest for thinner active layer devices.

Other embodiments of the invention are directed to a method of forming an array of concave or convex reflectors on a transparent electrode of a solar cell. In one embodiment of the invention, the array can be formed by inkjet printing concave features comprised of a curable resin on a transparent electrode or substrate adjacent to a transport electrode.

Methods and materials for producing an array of concave features by inkjet printing, including a method to impose a large contact angle to lenses so deposited, are disclosed in WO/2008/157604, published. Dec. 24, 2008, and incorporated herein by reference. Arrays with desired shapes, sizes, patterns and overlap can be formed by controlling: the viscosity of the resin; the resins rate of curing; the time period between deposition of the feature and irradiation; and the mode of feature deposition. The resin can be chosen to have a desired refractive index, and is chosen to be adherent to the electrode or substrate to which in is deposited. After formation of the array, the surface can be metalized, or otherwise rendered reflective to the incident light. In some embodiments of the invention, the concave features are metalized by vapor deposition on the resin to render them reflective. Metals that can be deposited include, but are not limited to: aluminum; silver; gold; iron; and copper.

In other embodiments of the invention, concave or convex features are formed by a roll to roll method using a mold or by stamping, using an optically transparent adhesive material for application to the transparent substrate or electrode to generate the array. The mold or stamp can be generated by any method including: curing of a resin around a template; micromachining; laser ablation; and photolithography. The template can be removable or sacrificial, being a feature that can be dissolved or decomposed after formation of the mold or stamp. The template can be formed by laser ablation, photolithography, other mechanical (drilling) micromachining, or replicated using an earlier generation mold or stamp before the end of its effective lifetime. For example, a close packed array of nearly identical polystyrene spheres in a flat tray as a template can be covered by a silicone resin and subsequently cured to yield a mold; when the silicone is fractured at approximately a height of one radius of the spheres upon delaminating the tray and spheres. A fluid curable resin can be placed in a tray with, for example, sacrificial spheres of a desired density such that they float as a monolayer with a desired density to give a desired feature orientation in fluid resin, wherein the sacrificial spheres can then be dissolved or decomposed after curing of the resin to form the mold.

The mold or stamp is used to form the features when pressed against a layer of a transparent resin having a desired refractive index applied to a surface. The mold's textured features can be on the face of a roller or a stamp, such that it can be systematically pressed onto the transparent resin in a manner that transfers the desired features to the resin. The transparent resin adheres to the surface, but does not adhere to the mold. The resin is then cured to form a textured transparent solid layer having the features imparted by the mold. Curing can be done by photochemical activation where the light is irradiated from the opposite surface to that where the transparent resin is deposited or to the deposition side either through the mold, or to the transparent resin after removal of the mold within a period of time before any significant flow distortion of the textured features occurs. Deposition can be carried out on a surface of the solar cell, for example, a transparent electrode or a transparent substrate upon which the electrode and active layers had been deposited on the face opposite the molded transparent layer. Alternately, the textured layer can be deposited on the substrate prior to deposition of electrode and active layers on the opposite face of the substrate. The transparent substrate can be rigid or flexible, and can be an inorganic glass or an organic plastic or resin. The transparent resin can be an optical adhesive, which is generally photocurable with a sufficient viscosity to spread only slowly on a surface to which it is applied.

In another embodiment of the invention, the transparent resin can be within a mold having the concave or convex features and a substrate placed onto the surface of the transparent resin. Subsequent curing of the resin and removal of the substrate results in a cured textured film with the feature from the mold.

Other embodiments of the invention are directed to a method of forming an array of pyramidal reflectors on a transparent electrode or its supporting substrate of a solar cell. In embodiments of the invention, pyramidal features are formed by a roll to roll method using a mold or stamping, with an adhesive optically transparent material for application to the transparent substrate or electrode to generate the array of pyramidal features. The mold or stamp can be generated by any method including: curing of a resin around a template; micromachining; laser ablation; and photolithography. The template can be removable or sacrificial, being a feature that can be dissolved, evaporated, or decomposed after formation of the mold or stamp. The template can be formed by: laser ablation; photolithography; other mechanical micromachining, such as drilling: or replicated using an earlier generation mold or stamp before the end of its effective lifetime.

The mold or stamp is used to form the features when pressed against a layer of a transparent resin having a desired refractive index applied to a surface. The molds textured features can be on the face of a roller or a stamp, such that it can be systematically pressed onto the transparent resin in a manner that transfers the desired features to the resin. The transparent resin adheres to the surface, but does not adhere to the mold. The resin is then cured to form a textured transparent solid layer having the features imparted by the mold. Curing can be done by photochemical activation, where the light is irradiated from the opposite surface to the surface upon which the transparent resin is deposited, or to the deposition side, either through the mold or to the transparent resin after removal of the mold within a period of time before any significant flow distortion of the textured features occurs. Deposition can be carried out on a surface of the solar cell, for example a transparent electrode or a transparent substrate upon which the electrode and active layers had been deposited on the face opposite the molded transparent layer. Alternately, the textured layer can be deposited on the substrate prior to deposition of electrode and active layers on the opposite face of the substrate. The transparent substrate can be rigid or flexible and can be an inorganic glass or an organic plastic or resin. The transparent resin can be an optical adhesive, which is generally photocurable with a sufficient viscosity to spread only slowly on a surface to which it is applied. After formation of the array of pyramids, the surface can be metalized or otherwise rendered reflective to the incident light. In some embodiments of the invention, the pyramidal features are metalized by vapor deposition on the cured resin to render them reflective. Metals that can be deposited include, but are not limited to: aluminum, silver, gold, iron, and copper.

In another embodiment of the invention, the transparent resin is within a mold having the pyramidal features and a substrate is placed onto the surface of the transparent resin. Subsequent curing of the resin and removal of the substrate results in the cured film with the pyramidal features of the mold.

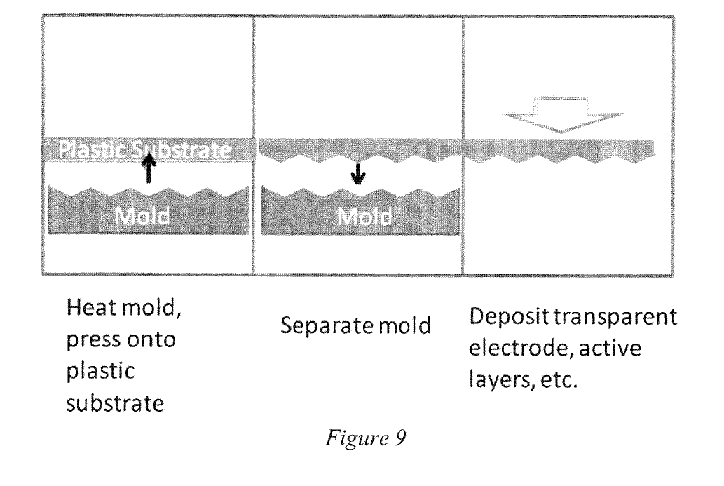

In another embodiment of the invention, a transparent substrate surface can be textured with an array of pyramids using a molding process. For plastic substrates, this can involve a roll-to-roll molding. A bare plastic substrate, as a sheet coming off of a source roll, can be softened with heat, for example, by being contacted with a heated roller, with the heated mold, or without contacting using a remote heat source, such as an infrared lamp. In one embodiment of the invention, as shown in FIG. 9, the substrate is placed in physical contact with a rigid mold having a template of the pyramids, which can be formed by a rolling method or other method. The mold or the substrate can be heated. The mold can he applied with pressure, for example by a roller on the other side of the plastic substrate, to imprint the features into the substrate and to form the pyramids on one substrate surface or face after the mold has been removed. The pressure can vary from the pressure imposed by gravity, by either the sheet resting on the mold, or the mold resting on the sheet to a pressure of even 1,000 psi, or more, as need for the materials chosen for the temperature used during molding at the desired rate of molding. One skilled in the art can readily envision or determine the necessary temperature and pressures needed for molding any given identified thermoplastic substrate. Subsequently, the opposite non-textured face of the substrate is used as a first surface for the subsequent sequential deposition of a transparent electrode, one or more active layers, a counter electrode, and any other necessary layers of the solar cell. The substrate can be a transparent thermosetting resin that is molded with one face having the array of pyramids, where the resin can be cured thermally or photochemically. The surface array of pyramids on glass substrates can be formed by molding the features during the glass manufacturing process using a large-area flat mold having a template of the pyramids for one face of the glass substrate. After formation of the array of pyramids, the surface can be metalized or otherwise rendered reflective to the incident light. In some embodiments of the invention, the pyramidal features are metalized by vapor deposition on the cured resin to render them reflective. Metals that can be deposited include, but are not limited to: aluminum; silver; gold; iron; and copper.

In other embodiments of the invention, a top textured surface can he formed on the surface opposite the reflector array of the solar cell. As described above in a manner analogous to formation of the back reflector array without a metallization step, the top textured surface can be formed by inkjet printing, stamping, roll to roll molding, or any other method described above. The back reflector array and the top textured surface can be formed sequentially or simultaneously. When the reflector array and top textured surface are formed sequentially, either surface can be deposited first. The top textured surface and the reflector array need not be formed by the same method. For example, the back reflector array can be formed by a stamping method, while the top textured surface can be formed by inkjet printing.

### Materials and Methods

A simple but effective light trapping design for organic solar cells (OSCs) that is compatible with roll-to-roll device manufacturing was examined. By molding, a pyramidal rear reflector is formed on a semi-transparent OSC employing two transparent electrodes sandwiching the organic active layer. The devices induce four passes of light through the active layer, due to total internal reflection at the light incident surface, effectively increases the optical path length within the active layer. The enhanced light harvesting leads to an increase in the short-circuit current density (Jsc) and PCE of the OSC. Pyramidal reflectors with a base angle of 30° were applied to devices with different thicknesses of poly(3-hexylthiophene) (P3HT) and [6,6]-phenyl-C61-butyric acid methyl ester (PCBM) as the active layers.

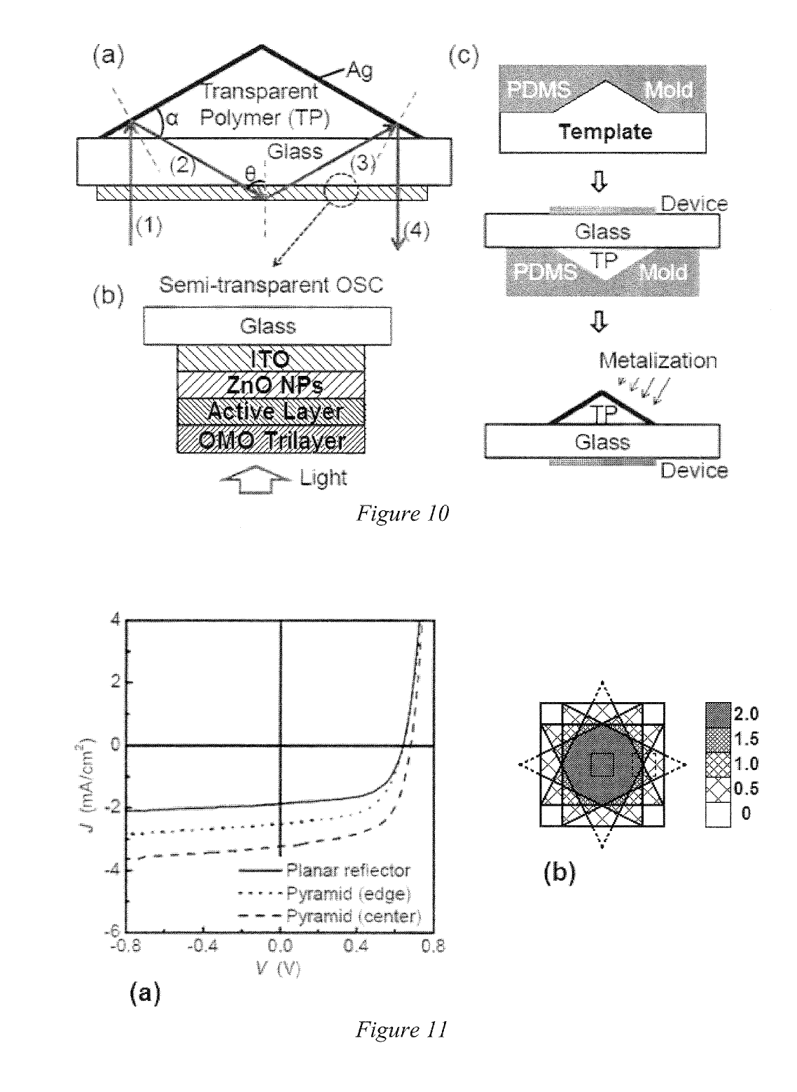

A design for an organic solar cell (OSC) with a pyramidal rear reflector exterior to a glass substrate is schematically shown in FIG. 10A. Upon incidence (1), the light passes through the active layer. Unabsorbed light is then reflected off the pyramidal rear reflector (2), directed into the active layer at angle θ from normal. Unabsorbed light is internally reflected at the device/air interface with an appropriate pyramid base angle (a). Two more passes, (3) and (4), of light through the active layer occur. With the reflector formed upon a planar substrate in this manner, the reflector structure does not alter the active layer structure, and existing device fabrication processes to form the OSC can be used.

Semi-transparent organic solar cells were fabricated on glass substrates that were pre-coated with an indium tin oxide (ITO) electrode. ZnO nanoparticles were synthesized using sol-gel process and were spin-coated onto the ITO layer, followed by spin-coating the P3HT:PCBM solution on the ITO electrode as the active layer. Devices having three different active layer thicknesses (tₐ=40, 70 and 100 nm) were fabricated by depositing solutions having different concentrations (9, 18 and 27 mg/mL) of P3HT:PCBM in chlorobenzene. All films were annealed at 150° C. for 30 minutes in a N₂ glove box. An oxide/metal/oxide (OMO) trilayer, where a 10 nm thick Au layer was sandwiched between 5 and 40 nm thick MoO₃ layers, was deposited by vacuum thermal evaporation on top of the active layer as the semi-transparent anode, to yield the device represented in FIG. 10B. Fabrication of the pyramidal rear reflectors is indicated in FIG. 10C, where a polydimethylsiloxane (PDMS) mold was replicated from a machined stainless steel template to have square pyramid feature where a=30° and with a base area of 1 cm². The base angle assures light reflected from one pyramidal facet does not directly strike any second surface of the pyramidal reflector before exiting the reflector and maximizes the optical path length for the second and third passes. A UV curable transparent polymer (TP) was placed in the PDMS mold, covered by the glass substrate, and cured under UV light (365 nm wavelength) for 5 minutes. Subsequently, a 200 nm thick Ag layer was thermally evaporated on the TP to form the reflecting surface of the reflector.

The J-V characteristics of semi-transparent OSCs, with smaller surface areas (2×2 mm²) than the pyramidal reflectors (1×1 cm²), and OSCs, with flat Ag mirrors directly deposited on the glass substrate, were measured under 1 sun simulated AM 1.5G solar illumination from Xe-arc lamp using an Agilent 4155C semiconductor parameter analyzer. Some of the small area OSCs were located concentric with the pyramid of the reflector and others were located near an edge of the pyramid of the reflector as indicated in FIG. 11B. As shown in FIG. 11A, for tₐ=40 nm, a 75% improvement in J_{sc} is observed for OSCs concentric with the pyramid and an improvement in J_{SP} of only 31% is observed for the device aligned near the edge of the pyramid relative to the OSCs with a flat reflector. Changes in the open-circuit voltage and fill factor of these devices are minimal, leading to the enhancement in PCE being approximately the same as that in J_{sc}. The location-dependent improvement is due to a non-uniform light intensity profile where incident light is reflected off all four facets of the pyramid, giving rise to different levels of reflected light intensity, as indicated in the inset by the density of lines. When placed at the center of the pyramid, (solid box in FIG. 11B), reflection off all four triangular pyramid facets reach the OSCs active area. For an OSC placed near the edge of the pyramid, (dashed box in FIG. 11 B), light reflected off only three or fewer pyramid facets enter much of the OSC's active layer.

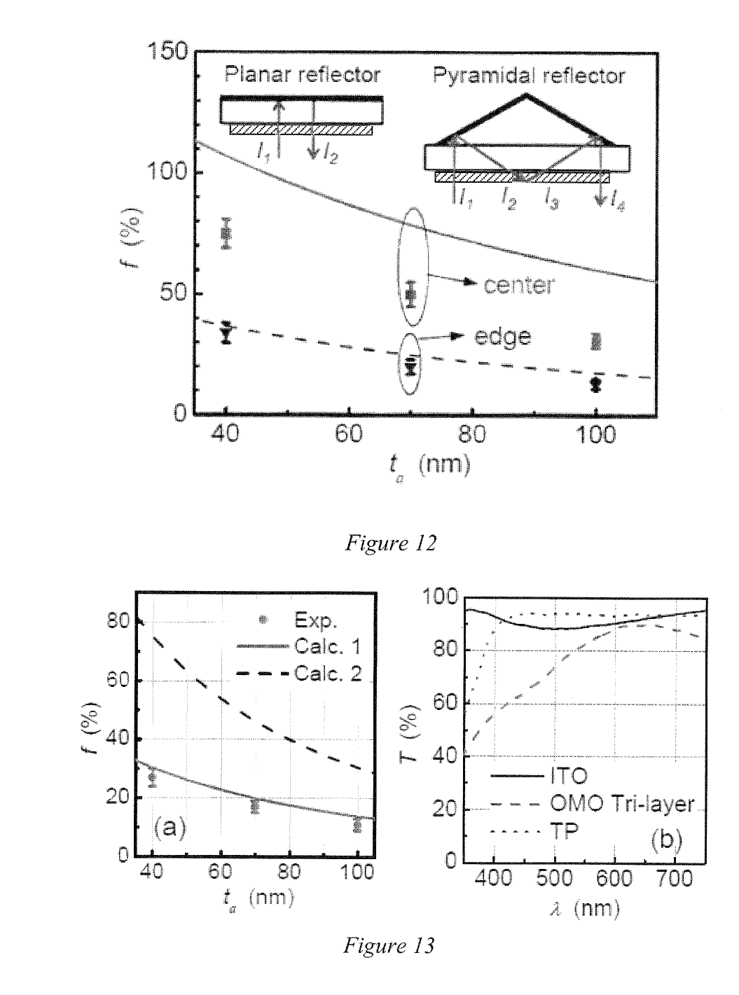

Ray-optics rules were used to calculate J_{sc} enhancement based on the lengthened optical path with pyramidal reflector. As indicated in the inset of FIG. 12, a device with a planar reflector has two light passes through the active layer, denoted as I₁ and I₂, which have equal path lengths of tₐ. As indicated in the inset of FIG. 12, a device with a pyramidal rear reflector results in four passes of light though the active layer due to the total internal reflection after the second pass. While the first and fourth passes have a path length of tₐ, the second and third passes have a path length of tₐ/cos s, where s is the angle from substrate normal for the light path through the active layer. Using a Beer's Law calculation with the known absorption coefficients of the active materials, the enhancement in total absorption when using a pyramidal rear reflector verses using a planar reflector was calculated, where the enhancement in absorption should be nearly equal to the enhancement in J_{sc}. As shown by lines in FIG. 12, the calculated enhancement factor, f, is significantly higher for devices positioned at the center of pyramid than for device positioned at the edge of the pyramid, but both indicate a decrease in f with an increase in tₐ. This is consistent with the first pass contributing more to the total light absorption to that of subsequent passes through a thick active layer. The experimental results, as indicated by symbols with error bars in FIG. 12, qualitatively agree with the trends predicted by calculations, although the experimental results are lower than the calculations predict, with greater discrepancies for devices concentric with the pyramid. The discrepancies can be attributed to the non-ideal surfaces of the pyramidal reflector and absorption and/or scattering of light in the transparent polymer (TP) in the reflector.

For OSCs having the identical dimensions as the pyramidal reflector (1×1 cm²), as shown in FIG. 13A, the Jₛₚ improvement is 27% for the devices where tₐ=40 nm, 17% for the devices where tₐ=70 nm, and 11% for the devices where tₐ=100 nm, which agrees well with calculated J_{sc} improvements, as indicated in FIG. 13A for the line labeled as Calc. 1. Due to the thickness of the glass substrate, about 1.1 mm, a portion of the reflected light goes outside the active area of the OSC even though the OSC has the same dimensions as the pyramid's base. The area to which light extends outside of the pyramids base and the equal sized OSC is indicated by the dashed triangles in FIG. 11B. This area of light loss can be minimized by using an array of pyramids with a size smaller than the OCS's surface. By using multiple small pyramids, the amount of the TP used, and the possible attenuation of light inside the pyramid by the TP, is also minimized. As shown in FIG. 13B, the OMO trilayer has lower transmittance than the commonly used ITO transparent electrode, particularly in the range below 550 nm, and the TP is less than 100% transparent. In an ideal case, if the electrodes and pyramid materials are 100% transparent, anfvalue of 75% for tₐ=40 nm and an f value of 30% for tₐ=100 nm should be possible based on calculations as indicated by the line labeled Calc. 2 in FIG. 13A.

All patents, patent applications, provisional applications, and publications referred to or cited herein are incorporated by reference in their entirety, including all figures and tables, to the extent they are not inconsistent with the explicit teachings of this specification.

It should be understood that the examples and embodiments described herein are for illustrative purposes only and that various modifications or changes in light thereof will be suggested to persons skilled in the art and are to be included within the spirit and purview of this application.

1.-31. (canceled)

32. A thin film solar cell, comprising a back reflector that comprises an array of reflective features of 1 to 1,000 μm in cross-section deposited on a flat surface.

33. The solar cell of claim 32, wherein the back features are of one or more shapes, sizes, and/or cross-sections.

34. The solar cell of claim 32, wherein the reflective features are concave or convex features.

35. The solar cell of claim 34, wherein the back features comprise hemispheres, hemi-ellipsoids, partial-spheres, partial-ellipsoids or any combination thereof.

36. The solar cell of claim 35, wherein the reflective features are pyramidal.

37. The solar cell of claim 36, wherein the array is periodic with the pyramidal features have triangular, square or hexagonal bases.

38. The solar cell of claim 32, wherein the back reflector comprises a reflective metal deposited on a photochemically cured or thermally cured transparent resin.

39. The solar cell of claim 38, wherein the transparent resin comprises an optical adhesive.

40. The solar cell of claim 38, wherein the back reflector further comprises TiO₂ nanoparticles, ZrO₂ nanoparticles, CeO₂ nanoparticles, lead zirconate tinate (PZT) nanoparticles, or any other transparent inorganic nanoparticles.

41. The solar cell of claim 38, wherein the metal comprises aluminum, silver, gold, iron, or copper.

42. The solar cell of claim 32, wherein the solar cell comprises an active layer comprises an inorganic semiconducting thin film comprising amorphous, nanocrystalline, microcrystalline, or polycrystalline forms of silicon, silicon germanium, CdTe, CdS, GaAs, Cu₂S, CuInS₂, CuZnSn(S,Se), or Cu(InₓGa₁₋ₓ)Se₂.

43. The solar cell of claim 42, wherein the active layer comprises an organic semiconducting thin film, wherein the organic semiconducting film comprises a small molecular weight organic compound or a conjugated polymer.

44. The solar cell of claim 42, wherein the active layer comprises a hybrid organic-inorganic semiconducting thin film comprising inorganic nanoparticles and a conjugated polymer or small molecular weight organic compound.

45. The solar cell of claim 32, further comprising a top transparent textured surface layer on the surface proximal to the incident light comprising an array of top features of 1 to 1,000 μm in cross-section deposited on a flat surface, wherein at least 60% of the flat surface is occupied by the features.

46. The solar cell of claim 45, wherein the cross-section of the top features is less than or equal to the thickness of a substrate having the flat surface.

47. The solar cell of claim 45, wherein the top features comprise hemispheres, hemi-ellipsoids, partial-spheres, partial-ellipsoids, cones, pyramids, prisms, half cylinders or any combination thereof.

48. The solar cell of claim 45, wherein the top textured surface layer comprises a photo-cured resin.

49. A method of forming a back reflector comprising an array of features on a surface of a thin film solar cell, comprising:
forming an array of features comprising a photocurable transparent resin to a surface;
curing the transparent resin by irradiation with electromagnetic radiation, wherein the array of features are fixed and adhered to the surface and wherein the surface is a surface of a transparent substrate or a transparent electrode; and
depositing a metal on said cured array of features.

50. The method of claim 49, wherein forming the array comprises inkjet printing the transparent resin in the shape of concave features on the surface.

51. The method of claim 49, wherein forming the array comprises:
depositing a layer of the transparent resin on the surface; and
contacting the layer with a mold having a template of the features.

52. The method of claim 51, wherein contacting comprises roll to roll imprinting or stamping with a mold.

53. A method of forming a solar cell having a back reflector comprising an array of features, comprising:
molding an array of features on a face of a transparent substrate;
depositing a metal on the array of features; and
depositing a transparent electrode on a second face of the transparent substrate opposite the array of pyramidal features.

54. The method of claim 53, wherein molding comprises contacting a mold having a template of the array of features with the transparent substrate comprising a thermoplastic sheet, and wherein one or both of the mold and the thermoplastic sheet are heated during contacting.

55. The method of claim 53, wherein molding comprises filling a mold having a template of the array of features on one face with a thermosetting resin and curing the resin thermally or photochemically to form the transparent substrate having the array of features on one face.

56. The method of claim 53, wherein molding comprises filling a mold having a template of the array of features on one face with a molten glass and solidifying the glass in the presence of the mold to form a transparent glass substrate having the array of features on one face.
